(19) United States
(12) Patent Application Publication
(10) Pub. No.: US 2017/0288202 A1
(43) Pub. Date: Oct. 5, 2017

(54) BATTERY CIRCUIT CONTACTORS

(71) Applicant: Faraday&Future Inc., Gardena, CA (US)

(72) Inventors: David Tarlau, Torrance, CA (US); Alan Lowell Barry, Torrance, CA (US)

(21) Appl. No.: 15/085,819

(22) Filed: Mar. 30, 2016

(51) Int. Cl. H01M 2/26; B23K 26/362; B23K 26/21; H05K 3/00; H05K 3/40

(52) U.S. Cl. CPC H01M 2/266; H05K 3/005; H05K 3/40; H05K 3/0026; B23K 26/21; B23K 26/362

(57) ABSTRACT

A method of making a printed wiring board (“PWB”) is disclosed. The PWB may be made by forming openings in a substrate. The substrate may be a dielectric substrate. The dielectric substrate may be at least partially uncured. A conductive sheet may be placed on one or both sides of the substrate to cover the openings. The substrate may be cured. The conductive sheet(s) may then be etched to form conductive tabs within the openings. The conductive tabs are free of dielectric material on both sides of the conductive tab. The conductive tabs may then be coupled to terminals of electrochemical cells to form a circuit as desired.

### CROSS-REFERENCE TO RELATED APPLICATIONS

This application is related to U.S. patent application Ser. No. 15/060,381, entitled “FLEXIBLE CIRCUIT FOR VEHICLE BATTERY,” filed on 3 Mar. 2016 and U.S. patent application Ser. No. 15/077,739, entitled “FLEXIBLE CIRCUIT FOR VEHICLE BATTERY,” filed on 22 Mar. 2016. Both of the above-referenced applications are hereby incorporated by reference in their entirety.

### BACKGROUND

Field

The present disclosure is related to methods of making contactors in a printed circuit board (“PCB”) or printed wiring board (“PWB”). In particular, a PWB for an electric vehicle battery and methods of making the same are described herein.

Description of the Related Art

PCB's and PWB's mechanically support and electrically connect electronic components using conductive traces, pads, and the like. Such devices are commonly made by etching away copper that has been laminated onto a non-conductive dielectric substrate. Flex circuits may employ flexible materials.

### SUMMARY

The devices, systems, and methods disclosed herein have several features, no single one of which is solely responsible for its desirable attributes. Without limiting the scope as expressed by the claims that follow, its more prominent features will now be discussed briefly. After considering this discussion, and particularly after reading the section entitled “Detailed Description of the Preferred Embodiment” one will understand how the features of the system and methods provide several advantages over traditional systems and methods.

In some implementations, a method of manufacturing a printed wiring board includes one or more of the following steps. The method may include, for example, forming at least one opening through a dielectric substrate, applying a conductor sheet to at least one side of the dielectric substrate to cover the at least one opening with the conductor sheet, and removing at least a portion of the conductor sheet in areas disposed over the at least one opening to form at least one conductive pad suspended over or within the opening. The method may also include curing the dielectric substrate. The curing may occur after the forming and applying steps. The method may also include placing the at least one conductive pad over a terminal of an electrochemical cell. The conductive pad may be secured and/or welded to the terminal of the electrochemical cell. A conductor sheet may be applied to two opposite sides of the dielectric substrate. The method may include removing at least a portion of the conductor sheet in areas disposed over the at least one opening to form at least two conductive pads suspended within the opening. A first conductive pad may be coupled to a positive terminal of an electrochemical cell and a second conductive pad may be coupled to the negative terminal of the cell.

In some implementations, a method of manufacturing a printed wiring board includes one or more of the following steps. The method may include, for example, forming a plurality of openings through a sheet of woven fibers that are pre-impregnated with uncured epoxy, applying a layer of copper to both sides of the sheet, curing the sheet with elevated heat and pressure, and etching at least a portion of the copper in areas disposed over the openings to form at least one copper connector suspended over or within the opening. The method may also include welding the at least one copper connector to a terminal of an electrochemical cell positioned below the sheet. The sheet of woven fibers that are pre-impregnated with uncured epoxy may be B-stage FR4 grade material. The plurality of openings may be formed by punching a plurality of openings through the sheet. The plurality of openings may be formed by laser etching a plurality of openings through the sheet.

In some implementations, a method of electrically connecting a plurality of battery cells includes one or more of the following steps. The method may include, for example, forming a plurality of openings through an at least partially uncured dielectric substrate, applying copper to opposites sides of the substrate and covering the plurality of openings, curing the dielectric substrate, etching at least a portion of the copper in areas disposed over the openings to form at least one copper connector positioned within each of the plurality of openings, placing the at least one copper connector on top of a battery cell, and welding the copper connector to a terminal of the battery. The welding may include laser welding. The method may also include etching at least a portion of the copper to form a conductive path from the at least one copper connector positioned within each of the plurality of openings to a second position spaced away from the at least one copper connector.

### BRIEF DESCRIPTION OF THE DRAWINGS

The following is a brief description of each of the drawings. From figure to figure, the same reference numerals have been used to designate the same components of an illustrated embodiment. The drawings disclose illustrative embodiments and particularly illustrative implementations in the context of connecting a plurality of electrochemical cells. They do not set forth all embodiments. Other embodiments may be used in addition to or instead. Conversely, some embodiments may be practiced without all of the details that are disclosed. It is to be noted that the Figures may not be drawn to any particular proportion or scale.

FIGS. 1-5 illustrate a process for fabricating a PWB according to an exemplary implementation.

FIG. 1A is a top plan view of a substrate having a plurality of openings therethrough.

FIG. 1B is a cross-sectional view of FIG. 1A taken about the line B-B.

FIG. 2A is a top plan view of the substrate of FIG. 1 that includes a sheet of conductive material applied to both sides of the substrate. As shown, the openings in the substrate are covered by the conductive sheets.

FIG. 2B is a cross-sectional view of FIG. 2A taken about the line B-B.

FIG. 3A is similar to FIG. 2A and illustrates the masking and etching of a top surface to form a PWB.

FIG. 3B is a cross-sectional view of FIG. 3A taken about the line B-B.

FIG. 4A is similar to FIG. 3A and illustrates the formation of a conductive tab formed within the openings.

FIG. 4B is a cross-sectional view of FIG. 4A taken about the line B-B.

FIG. 5 is the same as FIG. 4A with one of the tabs placed into contact with a terminal of an electrochemical cell.

FIG. 6A is a top plan view of a PWB according to another exemplary implementation.

FIG. 6B is a cross-sectional view of FIG. 6A taken about the line B-B.

FIG. 6C is a cross-sectional view of FIG. 6A taken about the line C-C.

### DETAILED DESCRIPTION OF THE PREFERRED EMBODIMENT

Disclosed herein is a process for fabricating a PWB in a simple and inexpensive manner. Such PWB's may be used, for example, to quickly and easily connect a plurality of electrochemical cells in a desired manner. The plurality of electrochemical cells may be connected in series and/or in parallel and/or in combinations thereof. A portion of the PWB may be mechanically and electrically coupled to one or more terminals of the electrochemical cells. In some aspects, the electrochemical cells have a positive terminal and a negative terminal on the same end. In some aspects the electrochemical cells are cylindrical and have the positive terminal and the negative terminal disposed on one of the circular ends of the cylinder. The electrochemical cells may be lithium ion batteries.

PWB's for connecting a plurality of electrochemical cells may include one or more conductive tabs. The conductive tabs may extend into an opening. The opening may be positioned above the electrochemical cells. The conductive tabs may be secured to the terminals by, for example, welding. In this way, a plurality of cells can be connected in any desired manner in a one step process using a PCB that is positioned over the cells and secured to the terminals.

Manufacturing such a PWB may difficult using traditional methods. For example, rigid PWB's are commonly made from large sheets of a dielectric substrate having copper laminated on, or copper rolled on, to both sides of the substrate. Such copper laminated substrates are readily available from bulk suppliers. The dielectric substrates may be glass-reinforced epoxy laminate sheets. Such dielectric substrates may include G10, G11, FR4, FR5, and FR6 grade materials. The copper laminated material is obtained and the copper and/or the dielectric is etched in the desired pattern.

However, it may be difficult and/or expensive to remove all of the dielectric material to create such a tab from these bulk materials. For example, the required laser time may be impractical for large scale manufacturing. Additional post process steps involving the removal of the dielectric with a mill or a laser are also commonly required. This removal process is expensive. In addition, there is a risk that fibers from the dielectric substrates are not removed from the entirety of the conductive tab—inhibiting the formation of a good electrical connection between the tab and the battery terminal.

While the fabrication process for flex PWB's allows for a conductive material, free of all dielectric material, to extend beyond the dielectric material, such flex PWB's are inherently more expensive than rigid PWB's because of the materials and processing that are used. Thus, there is a need for an inexpensive and less time consuming process that results in a conductive tab that is free of dielectric material.

The present disclosure allows for a fast and inexpensive process of fabricating a rigid PCB/PWB with conductive tab features that are free of dielectric material on both sides of the conductive tab. The fabrication process can be applied to PCB's/PWB's having any number of layers. While the present description details the fabrication of a two layer board, multi-layer boards of any combination may be made by simply repeating the process steps for the two layer board.

The manufacturing process may begin by forming one or more openings through a dielectric substrate. The substrate may be any substrate for use in PWB's. For example, the substrate may be FR4 grade material. More preferably, the substrate includes a fiber matrix that is pre-impregnated with an epoxy. The fiber matrix may include fiberglass. “Pre-preg” or “B-Stage” material is known in the art and includes material that is at least partially uncured. Most preferably, the substrate includes B-Stage FR4 grade material.

The one or more openings through the dielectric substrate may be formed by punching, drilling, laser etching, and the like. This results in a substrate having a plurality of openings therethrough. In some aspects, the substrate is formed to have at least one opening for each electrochemical cell that is to be connected by the PWB. The openings may be substantially circular in shape; however any shaped opening(s) may be used. For example, the openings may be elliptical, rectangular, or triangular.

The manufacturing process may continue by applying a conductive material to one or more sides of the substrate. The conductive material may cover the openings in the substrate such that the openings are no longer visible. In some aspects, both sides of the substrate are covered by the conductive material. The conductive material is preferably copper. In some aspects, copper foil is laminated onto one or more sides of the substrate. When B-stage FR4 grade material is used as the substrate, the lamination process may generate the heat and pressure necessary to convert the B-stage FR4 into standard FR4 core material. This process may result in a two layer copper-core-copper PWB having copper-copper in the areas where an opening was made through the substrate.

The manufacturing process may continue by etching away the conductive material in the desired manner. Chemical masking and/or etching may be used. The copper-copper areas, where an opening was made through the substrate, may be formed into one or more conductive tabs that are free of any substrate material. The conductive tabs may be suspended over and/or located within the openings. In some aspects, the conductive tabs span across the one or more openings. The conductive tabs may be configured to span across to one or more sides that define a perimeter of the opening. The conductive tabs may be electrically connected to the terminal of a battery placed below the PWB. The conductive tabs may then be connected in any desired manner by etching the conductive material as desired.

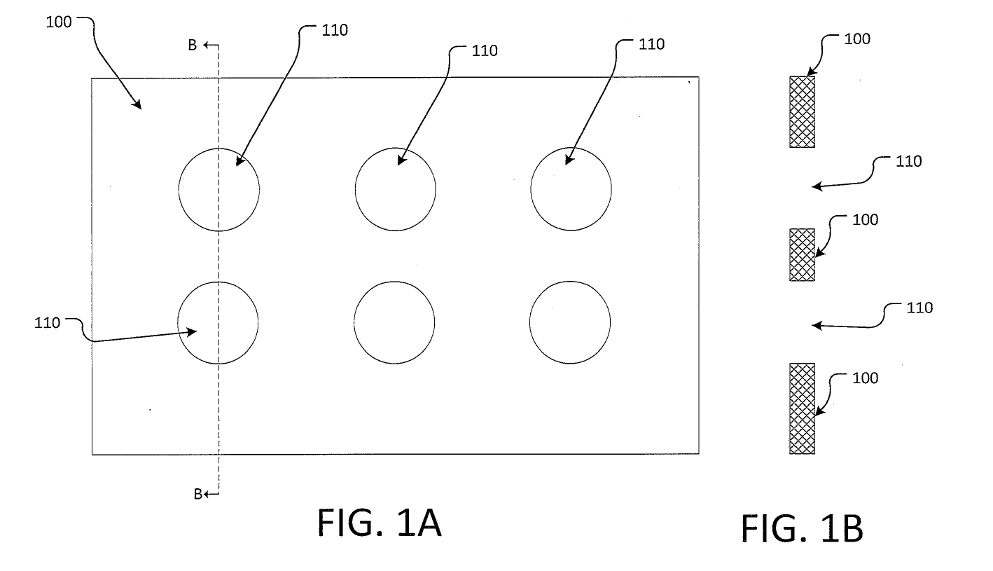

Turing now to FIGS. 1A-1B, a plurality of openings 110 are formed in a substrate 100. The substrate 100 may be a dielectric substrate. While the openings 110 are shown as circular, any shaped opening 110 may be formed through the substrate 100. In some aspects, one opening is provided for each cell that is to be connected by the PWB. However, additional openings 110 may be provided. In some aspects, for example, one opening is provided for each positive terminal that is to be connected and one opening is provided for each negative terminal that is to be connected. In other aspects, multiple openings are provided. For example, multiple openings may be provided for each negative terminal that is to be connected and one opening is provided for each positive terminal that is to be connected. In other implementations, multiple openings are provided for each positive and each negative terminal.

The substrate 100 may be substantially planar. The substantially planar surface may be defined by a longitudinal and lateral axis. The longitudinal axis may extend lengthwise from left to right in FIG. 1A. The lateral axis may extend from top to bottom in FIG. 1A. The transverse axis may be normal to the longitudinal and lateral axis and may define the thickness of the substantially planar surface. The thickness of the substrate may be seen in FIG. 1B. The thickness of the substrate 110 may to obtain the desired rigidity. In some aspects, the substrate 110 has a thickness of about six thousandths of an inch.

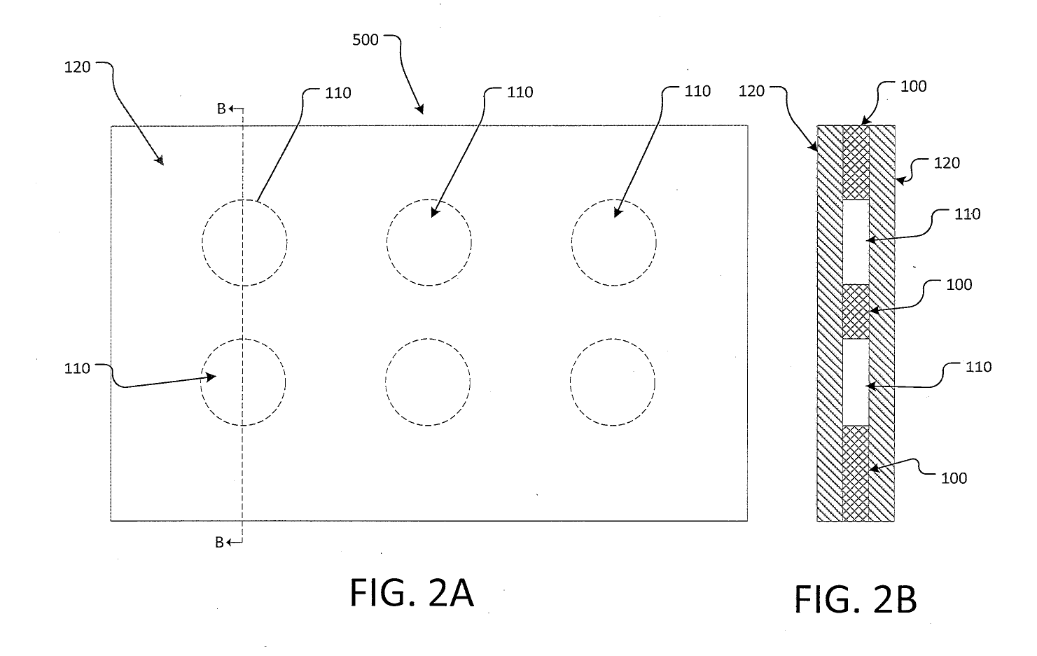

Turing to FIGS. 2A-2B, a conductive sheet 120 is applied to two opposite sides of the substrate 100 to form a coated substrate 500. Of course, in some implementations, a conductive sheet 120 is applied to only one side of the substrate 100. The openings 110 (shown in dotted lines) are thus covered on both sides by the conductive sheet 120. In some aspects, where the substrate 100 includes, for example, a pre-preg material, the coated substrate 130 is later cured. For example, the coated substrate may be placed into an oven, autoclave, or the like. In some aspects, copper foil is laminated to the substrate 100 using known techniques.

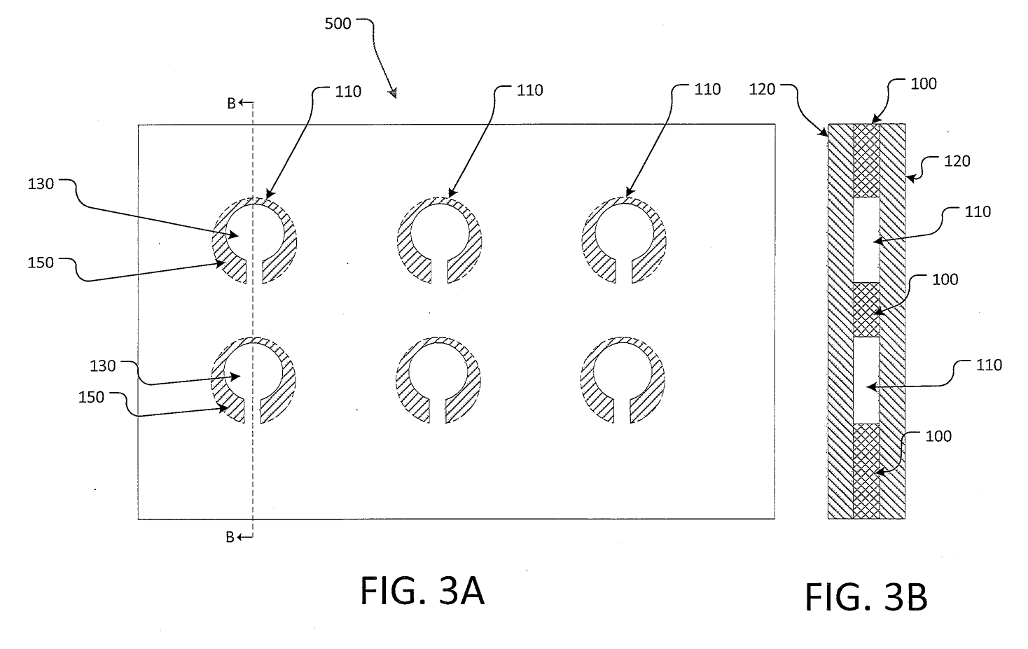

FIGS. 3A-3B illustrate that the conductive pattern on one or both sides of the coated substrate 500 may be masked and etched. The pad and trace mask 130 is shown as the same for all openings but may be varied across openings as desired. The area to be etched is represented by the cross-hatched areas 150 in FIG. 3A. After etching one or both sides of the coated substrate 500, the desired conductive pattern will remain in the masked areas. Various techniques for masking and/or etching are known in the art and include, for example, silk screen printing, photoengraving, PCB milling, and laser resist ablation.

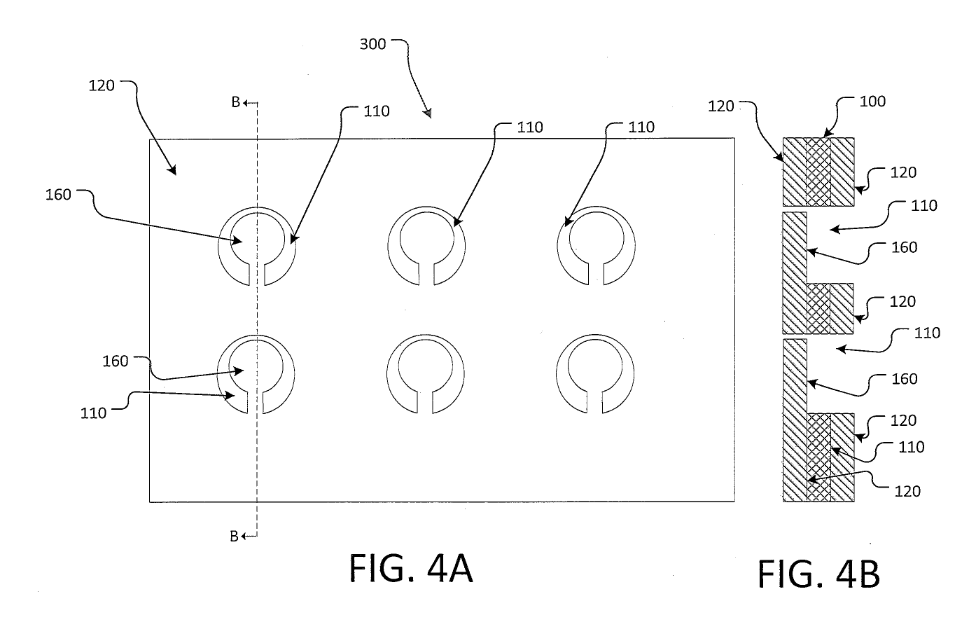

FIGS. 4A-4B show the resulting connector tabs 160 that are formed by etching away the conductive sheets 120 which forms a PWB 300 according to an exemplary implementation. As shown, the tabs 160 may be suspended within the openings 110. The tabs 160 may be connected to one another or routed to other conductive paths in the PWB as desired by etching traces in the desired manner. The tabs 160 extend out into the openings 110. The tabs 160 thus can remain suspended in the opening 110 and may be coupled to other electrical connections that are placed above and/or below the openings 110. In some aspects, the tabs 160 are coupled to the positive or negative terminal of an electrochemical cell. In some aspects, the electrochemical cells are positioned below the tabs 160. While FIG. 4B illustrates that the bottom conductive sheet 120 is fully removed from the opening 110 and the conductive sheet 120 is partially removed, the reverse scenario is also contemplated. Various amounts of material may be removed either or both conductive sheets 120 to form tabs 160 having various shapes and sizes.

The cross-sectional view of a tab 160 and opening 110, shown in FIG. 4A, illustrates that the conductive tab 160 may be free of substrate 100. That is to say, by forming the tab 160 within the openings 110, there is no risk that the tabs 160 include any dielectric material. In this way, a good electrical connection between the tab 160 and another conductive surface may be formed.

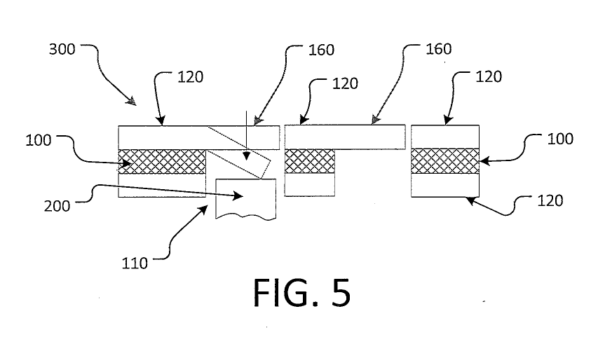

FIG. 5 illustrates that a terminal 200 of an electrochemical cell may be placed beneath the PWB 300. The electrochemical cell may be a lithium ion battery. As shown, the tab 160 may be pushed downward into the opening 110 and placed into contact with the terminal 200. The terminal 200 may be a positive or negative terminal. The tab 160 may be secured to the terminal with a conductive material. In some aspects, the tab 160 is welded to the terminal. The welding may be accomplished using, for example, a laser. A plurality of cells may be placed under such a PWB and rapidly connected in any desired manner according to the traces formed on the top and or bottom of the PWB.

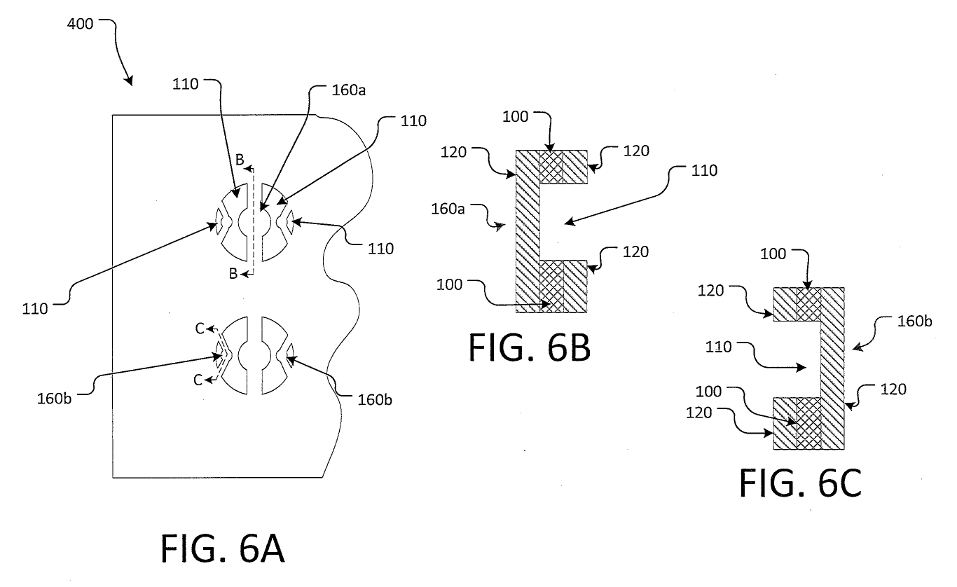

FIGS. 6A-6C illustrate another embodiment of a PWB 400 made according to the present disclosure. A shown, multiple conductive tabs 160 may be formed in the top and/or bottom conductive sheets 120. Tabs 160a and 160b may be formed to span across at least a portion of the opening 110. In some aspects, tabs 160a may be formed in the top conductive sheet 120 and be configured to contact a positive terminal of a cell and tabs 160b may be formed in bottom conductive sheet 120 and be configured to contact a negative terminal of a cell. Thus, multiple conductive tabs 160 may be formed in either of the conductive sheets 120 by etching the areas above the openings in the desired manner.

The foregoing description details certain embodiments of the systems, devices, and methods disclosed herein. It will be appreciated, however, that no matter how detailed the foregoing appears in text, the devices, systems, and methods can be practiced in many ways. As is also stated above, it should be noted that the use of particular terminology when describing certain features or aspects of the invention should not be taken to imply that the terminology is being re-defined herein to be restricted to including any specific characteristics of the features or aspects of the technology with which that terminology is associated. The scope of the disclosure should therefore be construed in accordance with the appended claims and any equivalents thereof.

It will be appreciated by those skilled in the art that various modifications and changes may be made without departing from the scope of the described technology. Such modifications and changes are intended to fall within the scope of the embodiments, as defined by the appended claims. It will also be appreciated by those of skill in the art that parts included in one embodiment are interchangeable with other embodiments; one or more parts from a depicted embodiment can be included with other depicted embodiments in any combination. For example, any of the various components described herein and/or depicted in the Figures may be combined, interchanged, or excluded from other embodiments.

What is claimed is:

1. A method of manufacturing a printed wiring board comprising:
forming at least one opening through a dielectric substrate;
applying a conductor sheet to at least one side of the dielectric substrate to cover the at least one opening with the conductor sheet; and
removing at least a portion of the conductor in areas disposed over the at least one opening to form at least one conductive pad suspended over or within the opening.

2. The method of claim 1, further comprising curing the dielectric substrate.

3. The method of claim 1, wherein the curing occurs after the forming and applying steps.

4. The method of claim 1, further comprising placing the at least one conductive pad over a terminal of an electrochemical cell.

5. The method of claim 4, further comprising securing the conductive pad to the terminal of the electrochemical cell.

6. The method of claim 4, further comprising welding the conductive pad to the terminal of the electrochemical cell.

7. The method of claim 1, wherein the conductor comprises copper.

8. The method of claim 1, wherein the dielectric substrate comprises a B-stage epoxy and fiberglass substrate.

9. The method of claim 1, wherein a conductor is applied to two opposite sides of the dielectric substrate.

10. The method of claim 1, further comprising removing at least a portion of the conductor in areas disposed over the at least one opening to form at least two conductive pads suspended within the opening.

11. The method of claim 10, further comprising coupling a first conductive pad to a positive terminal of an electrochemical cell and coupling a second conductive pad to the negative terminal.

12. A method of manufacturing a printed wiring board comprising:
forming a plurality of openings through a sheet of woven fibers that are pre-impregnated with uncured epoxy;
applying a layer of copper to both sides of the sheet;
curing the sheet with elevated heat and pressure; and
etching at least a portion of the copper in areas disposed over the openings to form at least one copper connector suspended over or within the opening.

13. The method of claim 12, further comprising welding the at least one copper connector to a terminal of an electrochemical cell positioned below the sheet.

14. The method of claim 12, wherein the sheet of woven fibers that are pre-impregnated with uncured epoxy is B-stage FR4 grade material.

15. The method of claim 12, forming a plurality of openings includes punching a plurality of openings through the sheet.

16. The method of claim 12, forming a plurality of openings includes laser etching a plurality of openings through the sheet.

17. A method of electrically connecting a plurality of battery cells comprising:
forming a plurality of openings through an at least partially uncured dielectric substrate;
applying copper to opposites sides of the substrate and covering the plurality of openings;
curing the dielectric substrate;
etching at least a portion of the copper in areas disposed over the openings to form at least one copper connector positioned within each of the plurality of openings;
placing the at least one copper connector on top of a battery cell; and
welding the copper connector to a terminal of the battery.

18. The method of claim 17, wherein the welding includes laser welding.

19. The method of claim 17, further comprising etching at least a portion of the copper to form a conductive path from the at least one copper connector positioned within each of the plurality of openings to a second position spaced away from the at least one copper connector.
